(19) United States
(12) Patent Application Publication
(10) Pub. No.: US 2008/0136320 A1
(43) Pub. Date: Jun. 12, 2008

(54) ORGANIC ELECTROLUMINESCENT ELEMENT AND METHOD OF MANUFACTURING THE SAME

(75) Inventor: Dong Kwon Choi, Yongin-Si (KR)

Correspondence Address: MARGER JOHNSON & MCCOLLOM, P.C., 210 SW MORRISON STREET, SUITE 400, PORTLAND, OR, 97204, US

(73) Assignee: JUSUNG ENGINEERING CO., LTD., Gwangju-Si (KR)

(21) Appl. No.: 11/948,658

(22) Filed: Nov. 30, 2007

(30) Foreign Application Priority Data
Dec. 6, 2006 (KR) 10-2006-0122965

(51) Int. Cl. H01L 51/54; H01L 51/56

(52) U.S. Cl. 313/504; 445/25

(57) ABSTRACT

An organic electroluminescent (EL) element and a method of manufacturing the same are provided. The EL element comprises an organic light emitting layer, an electron transport layer, an electron injection layer, an electrode formed on an upper side of a substrate, and a buffer layer. The buffer layer is formed between the electron transport layer and the electron injection layer, or between the electron injection layer and the electrode by an atomic layer deposition process. Thus, interfacial properties of the electron injection layer and the electrode are improved. Accordingly, leakage current at a threshold voltage or less of the EL element is prevented, and an electric property of the EL element is improved.

### CROSS REFERENCE TO RELATED APPLICATION

This application claims priority from Korean Patent Application No. 10-2006-0122965 filed on Dec. 6, 2006, in the Korean Intellectual Property Office, the disclosure of which is incorporated herein by reference in its entirety.

### BACKGROUND OF THE INVENTION

1. Field of the Invention

The present invention relates to an electroluminescent (hereinafter, referred to as “EL”) element and a method of manufacturing the same, and more particularly, to an organic EL element capable of ensuring a thickness uniformity in a large element and improving electric property by forming a buffer layer between an electron transport layer and an electron injection layer or between the electron injection layer and a cathode, and a method of manufacturing the same.

2. Description of the Related Art

Succeeding a liquid crystal display (LCD) and a plasma display panel (PDP), an organic EL element is a promising next generation flat panel display. In the organic EL element, light-emitting organic compounds are laminated and a voltage is supplied thereto to generate holes and electrons and thereby to emit light. The organic EL element may be called an organic electroluminescent display (OELD) or an organic light emitting diode (OLED).

Although an LCD displays an image by selective transmission of light and a PDP displays an image by plasma discharge, the organic EL element displays an image by an electroluminescence mechanism. In detail, an organic light emitting material is interposed between two electrodes, and voltage is applied to the electrodes. Electrons and holes are then injected into the organic layer from the anode and cathode, and are recombined with each other to generate recombination energy. The recombination energy stimulates organic molecules to emit light. The organic EL element has a self-emitting property, a wide viewing angle, a high definition, a high-quality image, and a high-speed response. Accordingly, the organic EL element is generally applied to small displays.

In the organic EL element, an electron transport layer is formed between an organic light emitting layer and a cathode. Electrons are injected to the electron transport layer from the cathode over the threshold voltage. Therefore, an electron injection layer is formed between the electron transport layer and the cathode in order to enhance injection of the electrons from the cathode into the electron transport layer.

In the related art, the electron injection layers are typically made of an ionic bonding compound of alkali metal such as a Li-containing layer and an Al-containing layer. However, the electron injection layers are deposited by a molecular beam epitaxy (MBE) process which is one of a gas phase process, and it is thereby difficult to form an element having a large area. That is, although excellent crystallinity can be obtained by MBE process, it is difficult to ensure thickness uniformity over a large area.

In addition, a thickness of the electron injection layer should be controlled in a range of about 10 Å. However, it is difficult to ensure the thickness uniformity while controlling the deposition thickness at around 10 Å simultaneously. If the thickness uniformity is degraded, uniformity of electrical properties of the device is also degraded over the substrate, for example, leakage current occurs.

### SUMMARY OF THE INVENTION

An aspect of the invention provides an organic EL element capable of improving an electric property thereof by forming a buffer layer between an electron transport layer and an electron injection layer, or between the electron injection layer and a cathode, and a method of manufacturing the same.

Another aspect of the invention provides an organic EL element which is provided with a buffer layer between an electron injection layer and a cathode by using an atomic layer deposition process to improve interfacial properties of the electron injection layer and the cathode, thus improving an electric property of the organic EL element, and a method of manufacturing the same.

An organic EL element according to an exemplary embodiment of the present invention includes: an organic light emitting layer; an electron transport layer; an electron injection layer; an electrode formed on an upper side of a substrate; and a buffer layer formed between the electron transport layer and the electron injection layer, or between the electron injection layer and the electrode. The electrode is formed by an atomic layer deposition process.

The organic EL element further may include another electrode, a hole injection layer, and a hole transport layer which are formed between the substrate and the organic light emitting layer, and an electron transport layer which is formed between the organic light emitting layer and the electron injection layer.

The buffer layer may include an insulating layer.

The buffer layer may include a silicon oxide film or a ferroelectric film.

The buffer layer maybe selected from silicon oxide (SiO₂), hafnium oxide (HfO₂), zirconium oxide (ZrO₂), tantalum oxide (Ta₂O₅), titanium oxide (TiO₂) zinc oxide (ZnO), niobium oxide (Nb₂O₅) yttrium oxide (Y₂O₅), silicon nitride (Si₃N₄), silicon oxynitride (SiON), aluminum nitride (AlN), aluminum oxynitride (AlON), and combinations thereof. The buffer layer may be formed as a mono-layer or formed by laminating two or more layers.

The buffer layer may be formed by using an atomic layer deposition process.

The buffer layer may be formed by repeatedly depositing the mono-layer of the buffer layer one to four times.

The buffer layer may be formed to have a thickness capable of preventing the organic layer from being damaged during deposition of the electrode by sputtering.

The buffer layer may be formed to have a thickness of about 10 Å.

method of manufacturing an organic EL element according to the exemplary embodiment of the invention may include loading a substrate on which an electron injection layer is formed into a reaction chamber, forming a buffer layer on an upper side of the electron injection layer by an atomic layer deposition process, and forming an electrode on an upper side of the buffer layer.

The buffer layer may include a silicon oxide film or a ferroelectric film.

The buffer layer may be formed by using an atomic layer deposition process.

The buffer layer may be formed by repeatedly depositing a mono-layer of the buffer layer one to four times. The buffer layer may be formed to have a thickness capable of preventing the organic layer from being damaged during deposition of the electrode by sputtering. The buffer layer may be formed to have a thickness of about 10 Å.

A method of manufacturing an organic EL element according to the exemplary embodiment of the invention may include loading a substrate on which an electron transfer layer is formed into a reaction chamber, forming an buffer layer on an upper side of the electron transfer layer by an atomic layer deposition process, and forming an electron injection layer and electrode on an upper side of the buffer layer.

The buffer layer may include a silicon oxide film or a ferroelectric film.

The buffer layer may be formed by using an atomic layer deposition process.

The buffer layer may be formed by repeatedly depositing a mono-layer of the buffer layer one to four times. The buffer layer may be formed to have a thickness capable of preventing the organic layer from being damaged during deposition of the electrode by sputtering. The buffer layer may be formed to have a thickness of about 10 Å.

### BRIEF DESCRIPTION OF THE DRAWINGS

The above and other features and advantages of the present invention will become more apparent by describing in detail preferred embodiments thereof with reference to the attached drawings in which:

FIG. 1 is a sectional view of an electroluminescent element according to an exemplary embodiment of the present invention; and

FIG. 2 is a flow chart illustrating a formation of aluminum oxide as a buffer layer of the electroluminescent element according to the exemplary embodiment of the present invention using an atomic layer deposition process.

### DESCRIPTION OF THE PREFERRED EMBODIMENTS

Hereinafter, embodiments of the invention will be described in detail with reference to the accompanying drawings. The present invention may, however, be embodied in many different forms and should not be construed as being limited to the embodiments set forth herein. Rather, these embodiments are provided such that this disclosure will be thorough and complete and will fully convey the concept of the invention to those skilled in the art.

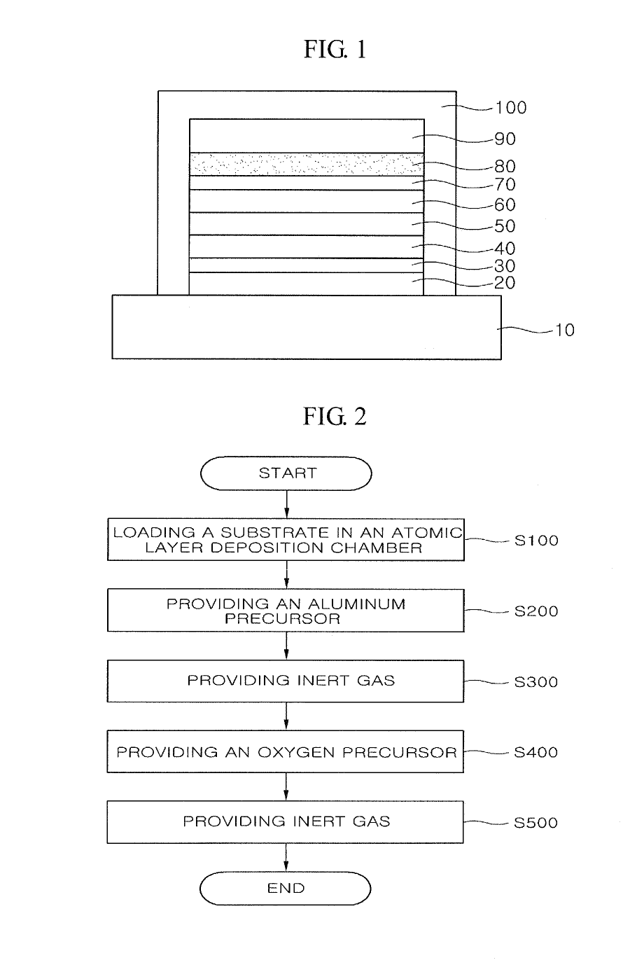

With reference to FIG. 1, in an organic EL element according to an exemplary embodiment of the present invention: a first electrode 20; a hole injection layer 30; a hole transport layer 40; an organic light emitting layer 50; an electron transport layer 60; an electron injection layer 70; a buffer layer 80; and a second electrode 90 are sequentially formed in a predetermined area on a substrate 10. In addition, a protective layer 100 is further formed to protect the organic EL element from moisture or oxygen from outside.

A silicon substrate or a glass substrate maybe used as the substrate 10. In a case of a flexible display, a plastic substrate (PE, PES, PET, PEN or the like) may be used.

The first electrode 20 is an anode used for hole injection, and formed of a transparent metal oxide which has high work function and allows light emitted in the element to get outside, for example, indium tin oxide (ITO), to have a thickness of about 150 nm. However, although the ITO has an excellent optical transparency, but is not easy to control. Accordingly, chemically-doped conjugated polymers including polythiophene or the like which has a desirable stability may be used to form the anode. Meanwhile, the first electrode 20 may be made of a metallic substance having a high work function. In this case, efficiency degradation due to a non-emitting recombination at the first electrode 20 can be prevented.

The hole injection layer 30 supplies holes supplied from the first electrode 20 to the hole transport layer 40, and is formed by using copper phthalocyanine or the like to have a thickness of about 15 nm.

The hole transport layer 40 is formed to have a thickness of about 40 nm by using TPD (N,N′-diphenyl-N,N′-bis-(3-methylphenyl)-1,1′-biphenyl-4,4′-diamine) which is a diamine derivative or poly(9-vinylcarbazole) which is a photoconductive polymer.

In addition, the organic light emitting layer 50 is formed to have a thickness of about 60 nm by using a monomolecular organic EL material such as Alq3 (tris(8-hydroxyquinoline) aluminum), anthracene or the like; and a polymer organic EL material such as PPV (poly(p-phenylenevinylene)), polythiophene (PT), and derivatives thereof.

The electron transport layer 60 is formed by using a derivative of oxadiazole or the like.

The electron injection layer 70 enables electrons to be effectively injected at a threshold voltage or more of the organic EL element, so that the organic EL element can work effectively. The electron injection layer 70 is formed to have a thickness of about 10 Å by using lithium (Li), lithium fluorine (LiF), Liq or the like by an MBE process.

The buffer layer 80 which is formed of an insulating layer is formed between the electron injection layer 70 and the second electrode 90. The insulating layer of the buffer layer 80 is made of silicon oxides or a ferroelectric (High-k) material. The insulating layer prevents leakage current at a threshold voltage or less of the organic EL element between the electron injection layer 70 and the second electrode 90.

In addition, the buffer layer 80 is formed by an atomic layer deposition (ALD) process. The buffer layer 80 is formed to have a thickness of about 10 Å. The thickness of the buffer layer 80 may depend on the thickness of the electron injection layer 70, and may become thicker or thinner according to the dielectric constant of the buffer layer 80. In the atomic layer deposition process, a uniform film having a thickness about 10 Å may be deposited to have a large area. If the deposition of the mono-layer is repeated one to four times by the atomic layer deposition process, the buffer layer having a thickness in the above-mentioned range may be formed. The buffer layer may be formed to have a thickness capable of preventing the organic layer from being damaged during deposition of the electrode by sputtering.

The insulating layer of the buffer layer 80 may be selected from silicon oxide (SiO₂), hafnium oxide (HfO₂), zirconium oxide (ZrO₂), tantalum oxide (Ta₂O₅), titanium oxide (TiO₂), zinc oxide (ZnO), niobium oxide (Nb₂O₅), yttrium oxide (Y₂O₅), silicon nitride (Si₃N₄), silicon oxynitride (SiON), aluminum nitride (AlN), aluminum oxynitride (AlON) and combinations thereof. The insulating layer is formed of a mono-layer or formed by laminating two or more layers.

The second electrode 90 is a cathode which is an electron injection electrode. The second electrode 90 is formed of a metal having low work function such as calcium (Ca), magnesium (Mg), aluminum (Al) and the like. Such a metal having low work function can lower a barrier between the second electrode 90 and the organic light emitting layer 50, and thus high current density can be obtained during injection of the electrons, whereby light emitting efficiency of the element can be increased. That is, calcium (Ca) has the lowest work function and, therefore, has a high efficiency. On the other hand, aluminum (Al) has relatively high work function and, therefore, has a low efficiency. However, calcium (Ca) is easily oxidized by oxygen or moisture in the air, but aluminum (Al) is relatively stable in the air. Accordingly, aluminum (Al) may be used as the material of the second electrode 90.

Meanwhile, the protective layer 100 is provided to protect the organic EL element which is formed as described above from oxygen or moisture from outside. The protective layer is formed of metal such as stainless steel or glass. The metal or glass is processed to have a can or cap shape having a predetermined space inside. A moisture absorbing agent is provided in a powder form in the space to absorb moisture, or attached in a film form by a double-sided tape. The protection can is attached to the substrate on which the organic EL element is mounted using a sealing agent to form the protective layer. Further, the protective layer may be formed on an upper side of the organic EL element by laminating an organic substance and an epoxy resin, or an inorganic substance and an epoxy resin. The protective layer may be formed to have a multi-layered structure by the atomic layer deposition process.

As described above, the organic EL element according to the exemplary embodiment of the present invention emits light downward. However, the direction of emitted light is not limited thereto, but the organic EL element may be formed to emit light upward. In order to emit light upward, two different types of organic EL elements may be employed. First type of the organic EL element is formed by subsequently laminating a cathode, a buffer layer, an electron injection layer, an electron transport layer, an organic light emitting layer, a hole transport layer, a hole injection layer, and an anode on an opaque substrate such as a silicon substrate. Second type of the organic EL element has the same structure as the organic EL element which emits light downward, except that a cathode is deposited as thin as possible in order to be made transparent and another transparent electrode is deposited thereon. A description on the laminated films of the organic EL element which emits light upward is the same as that of the organic EL element which emits light downward shown in FIG. 1. Therefore, a detailed description thereof will be omitted for convenience of the description.

FIG. 2 is a flow chart illustrating a formation of aluminum oxide as a buffer layer of the electroluminescent element according to the exemplary embodiment of the present invention using an atomic layer deposition process.

With reference to FIG. 2, the substrate on which the electron injection layer is formed is loaded in an atomic layer deposition chamber (S100). An aluminum precursor is provided into the deposition chamber with carrier gas to form the buffer layer, and the aluminum precursor is then adsorbed on the electron injection layer (S200). Inert gas is provided into the deposition chamber to purge the unreacted precursor (S300). Subsequently, an oxygen precursor is provided into the deposition chamber and then reacts with the aluminum precursor adsorbed on the electron injection layer (S400). Inert gas is provided to purge the unreacted precursor (S500). The above-mentioned procedure is considered as one cycle through which an aluminum oxide mono-layer is formed. Therefore, the cycle is repeated several times until aluminum oxide is deposited to a desired thickness. The deposition time required for a single cycle may depend on a condition such as flow amounts of the precursors, and the flow amount of the precursor may depend on the size of the substrate.

Various buffer layers may be formed by using silicon oxide (SiO₂), hafnium oxide (HfO₂), zirconium oxide (ZrO₂), tantalum oxide (Ta₂O₅), titanium oxide (TiO₂), zinc oxide (ZnO), niobium oxide (Nb₂O₅), yttrium oxide (Y₂O₅), silicon nitride (Si₃N₄), silicon oxynitride (SiON), aluminum nitride (AlN), aluminum oxynitride (AlON) or the like according to a process similar to the above-mentioned procedure.

According to another exemplary embodiment of the present invention, a multi-layered structure of oxides and nitrides may be formed as well as the mono-layered structure described above. That is, a double-layered structure of TiO₂/SiO₂ or a sandwiched structure of Al₂O₃/TiO₂/Al₂O₃ may be formed while controlling the thickness thereof simultaneously.

Further, although the buffer layer is formed between the electron injection layer and the cathode in the exemplary embodiment, the buffer layer may be formed between the electron transport layer and the electron injection layer.

As described above, in the exemplary embodiment of the present invention, a buffer layer including an insulating layer is provided between an electron transport layer and an electron injection layer, or between the electron injection layer and a cathode to improve interfacial properties of the electron injection layer and the cathode. Accordingly, leakage current at a threshold voltage or less of an organic EL element can be prevented and, therefore, an electric property of the organic EL element can be improved. Further, the buffer layer can protect the organic layers from energetic ions and electrons generated during a sputtering process by which the cathode is deposited.

Furthermore, the buffer layer can be deposited on a large substrate to have a thickness around 10 Å, which is a requirement of a buffer layer, by using an atomic layer deposition process

Although the invention has been described with reference to the accompanying drawings and the preferred embodiments, the invention is not limited thereto, but is defined by the appended claims. Therefore, it should be noted that various changes and modifications can be made by those skilled in the art without departing from the technical spirit of the appended claims.

What is claimed is:

1. An organic electroluminescent (EL) element comprising:
an organic light emitting layer;
an electron transport layer;
an electron injection layer;
an electrode formed on an upper side of a substrate; and
a buffer layer formed between the electron transport layer and the electron injection layer, or between the electron injection layer and the electrode by an atomic layer deposition process.

2. The organic EL element of claim 1, further comprising:
another electrode, a hole injection layer, and a hole transport layer formed between the substrate and the organic light emitting layer.

3. The organic EL element of claim 1, wherein the buffer layer includes an insulating layer.

4. The organic EL element of claim 1, wherein the buffer layer includes a silicon oxide film or a ferroelectric film.

5. The organic EL element of claim 1, wherein the buffer layer comprises one selected from the group consisting of silicon oxide (SiO₂), hafnium oxide (HfO₂), zirconium oxide (ZrO₂), tantalum oxide (Ta₂O₅), titanium oxide (TiO₂), zinc oxide (ZnO), niobium oxide (Nb₂O₅), yttrium oxide (Y₂O₅), silicon nitride (Si₃N₄), silicon oxynitride (SiON), aluminum nitride (AlN), aluminum oxynitride (AlON) and combinations thereof; and
the buffer layer is formed as a mono-layer or formed by laminating two or more layers.

6. The organic EL element of claim 1, wherein the buffer layer is formed by repeatedly depositing the mono-layer of the buffer layer one to four times.

7. The organic EL element of claim 1, wherein the buffer layer is formed to have a thickness capable of preventing the organic layers from being damaged during deposition of the electrode by sputtering.

8. The organic EL element of claim 7, wherein the buffer layer is formed to have a thickness of about 10 Å.

9. A method of manufacturing an organic electroluminescent (EL) element, comprising:
loading a substrate on which an electron injection layer is formed into a reaction chamber;
forming a buffer layer on an upper side of the electron injection layer using an atomic layer deposition process; and
forming an electrode on an upper side of the buffer layer.

10. The method of claim 9, wherein the buffer layer includes a silicon oxide film or a ferroelectric film.

11. The method of claim 9, wherein the buffer layer is formed by repeatedly depositing a mono-layer of the buffer layer one to four times.

12. The method of claim 9, wherein the buffer layer is formed to have a thickness capable of preventing the organic layers from being damaged during deposition of the electrode by sputtering.

13. The method of claim 12, wherein the buffer layer is formed to have a thickness of about 10 Å.

14. A method of manufacturing an organic electroluminescent (EL) element, comprising:
loading a substrate on which an electron transfer layer is formed into a reaction chamber;
forming a buffer layer on an upper side of the electron transfer layer using an atomic layer deposition process; and
forming an electron injection layer and an electrode on an upper side of the buffer layer.

15. The method of claim 14, the buffer layer may include a silicon oxide film or a ferroelectric film.

16. The method of claim 14, wherein the buffer layer is formed by repeatedly depositing a mono-layer of the buffer layer one to four times.

17. The method of claim 14, wherein the buffer layer is formed to have a thickness capable of preventing the organic layers from being damaged during deposition of the electrode by sputtering.

18. The method of claim 17, wherein the buffer layer is formed to have a thickness of about 10 Å.
